(19) United States
(12) Patent Application Publication
(10) Pub. No.: US 2022/0246411 A1
(43) Pub. Date: Aug. 4, 2022

(54) METHOD OF DEPOSITING A MATERIAL ON A SUBSTRATE

(71) Applicant: Applied Materials, Inc., Santa Clara, CA (US)

(72) Inventor: Anke HELLMICH, Kahl (DE)

(21) Appl. No.: 17/617,555

(22) PCT Filed: Jun. 24, 2019
(86) PCT No.: PCT/EP2019/066696

§ 371 Date: Dec. 8, 2021

(51) Int. Cl. H01J 37/34; C23C 14/35; C23C 14/08

(52) U.S. Cl. CPC H01J 37/3426; C23C 14/086; C23C 14/352; H01J 37/3405

(57) ABSTRACT

A method of depositing a material on a substrate is described. The method includes sputtering at least a component of the material from a first rotary target with a first magnet assembly and a second rotary target with a second magnet assembly. The first magnet assembly within the first rotary target provides a first plasma confinement in a first direction facing towards the second rotary target. The second magnet assembly within the second rotary target provides a second plasma confinement in a second direction facing towards the first rotary target.

### TECHNICAL FIELD

Embodiments of the present disclosure relate to a deposition of material on a substrate. Embodiments of the present disclosure particularly relate to deposition of material on a substrate by facing target sputtering.

### BACKGROUND

Deposition of material on a substrate has many applications in various technical fields. Sputtering is a method for deposition of a material on a substrate. Sputtering can be associated with a bombardment of the substrate, particularly a film located on the substrate, with energetic particles. The bombardment may have a disadvantageous influence on the properties of a material, particularly a film, located on the substrate. To avoid the bombardment, facing target sputtering (FTS) systems were devised. In a FTS system, instead of facing the substrate directly, targets face each other. However, the stability of the sputtering plasma in conventional FTS systems is limited. The suitability of conventional FTS systems for the use in mass production is impaired.

In view of the above, it is beneficial to provide improved methods of depositing a material on a substrate.

### SUMMARY

According to an embodiment, a method of depositing a material on a substrate is provided. The method includes sputtering at least a component of the material from a first rotary target with a first magnet assembly and a second rotary target with a second magnet assembly. The first magnet assembly within the first rotary target provides a first plasma confinement in a first direction facing towards the second rotary target. The second magnet assembly within the second rotary target provides a second plasma confinement in a second direction facing towards the first rotary target.

According to an embodiment, a system for depositing a material is provided. The system includes a first rotary cathode with a first magnet assembly and a second rotary cathode with a second magnet assembly. The system is configured such that during deposition of the material, the first magnet assembly within the first rotary cathode is configured to provide a first plasma confinement in a first direction facing towards the second rotary cathode.

The present disclosure is to be understood as encompassing apparatuses and systems for carrying out the disclosed methods, including apparatus parts for performing each described method aspect. Method aspects may be performed for example by hardware components, by a computer programmed by appropriate software or by any combination of the two. The present disclosure is also to be understood as encompassing methods for operating described apparatuses and systems. Methods for operating the described apparatuses and systems include method aspects for carrying out every function of the respective apparatus or system.

### BRIEF DESCRIPTION OF THE DRAWINGS

So that the features recited above can be understood in detail, a more particular description of the subject matter briefly summarized above may be provided below by reference to embodiments. The accompanying drawings relate to embodiments and are described in the following:

FIG. 1 shows a system for depositing a material, according to embodiments described herein;

FIG. 2 shows a system for depositing a material, according to embodiments described herein;

FIG. 3 shows a system for depositing a material, according to embodiments described herein; and

FIG. 4 is a chart illustrating a method of depositing a material on a substrate, according to embodiments described herein.

### DETAILED DESCRIPTION OF EMBODIMENTS

Reference will now be made in detail to the various embodiments, wherein one or more examples of the embodiments are illustrated in the figures. Within the following description of the drawings, the same reference numbers refer to same components. Generally, only the differences with respect to individual embodiments are described. Each example is provided as an explanation and is not meant as a limitation. Further, features illustrated or described as part of one embodiment can be used on or in conjunction with other embodiments to yield yet a further embodiment. It is intended that the description includes such modifications and variations.

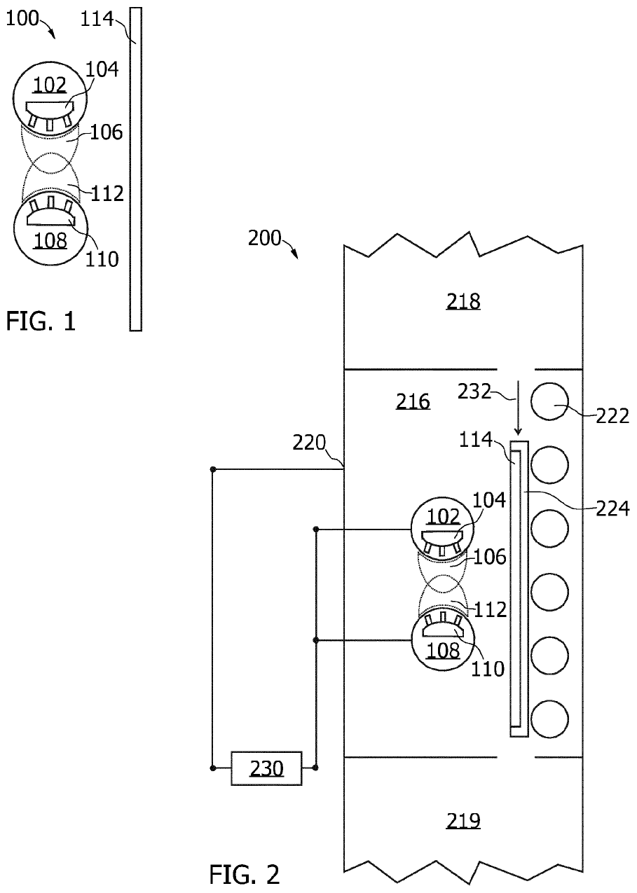

FIG. 1 shows a system for depositing a material, according to embodiments described herein. The system 100 includes a first rotary target 102 with a first magnet assembly 104. The system further includes a second rotary target 108 with a second magnet assembly 110. The first magnet assembly is positioned within the first rotary target. The second magnet assembly is positioned within the second rotary target. The rotary targets can be operated to face each other. For example, the first magnet assembly provides a first plasma confinement in a first direction facing towards the second rotary target and the second magnet assembly provides a second plasma confinement in a second direction facing towards the first rotary target.

During deposition of the material the first magnet assembly 104 within the first rotary target 102 provides a first plasma confinement 106 in a first direction facing towards the second rotary target 108. During deposition of the material the second magnet assembly 110 within the second rotary target 108 may provide a second plasma confinement 112 in a second direction facing towards the first rotary target 102. Plasma associated with the sputter deposition may be trapped between the first and the second rotary target. The first and the second plasma confinement may overlap at least partially. Typically, the first and the second rotary target are neighboring targets. In particular, there are no further targets positioned in a region between the first and the second rotary target.

In the context of the present disclosure, a plasma confinement is particularly to be understood as a plasma confinement region. A plasma confinement region may be understood as a region where the amount of plasma is increased relative to the environment, particularly due to the effect of the magnetic field associated with a magnet assembly of a rotary target. In the context of the present disclosure, providing a plasma confinement in a direction is particularly to be understood as providing the plasma confinement such that a main direction of the plasma confinement is positioned in that direction. Particularly in embodiments where the magnet assembly includes a permanent magnet, providing a plasma confinement in a direction facing a rotary target may be understood as providing the magnet assembly at a position such that the magnet assembly faces the rotary target, e.g. a neighboring rotary target.

Generally, a magnet assembly positioned within a rotary target may enable magnetron sputtering. As used herein, “magnetron sputtering” refers to sputtering performed using a magnetron, i.e. a magnet assembly. A magnet assembly is particularly to be understood as a unit capable of generating a magnetic field. A magnet assembly may include one or more permanent magnets. The permanent magnets may be arranged within a rotary target such that free electrons are trapped within the generated magnetic field. The magnet assembly can be provided within a backing tube of the rotary target or within the target material tube. The first rotary target and the second rotary target may both be a cathode. The system may be configured for DC sputtering. In embodiments, the system may be configured for pulsed DC sputtering.

A rotary target is particularly to be understood as a rotatable sputtering target. In particular, the rotary target may be a rotatable cathode including a material to be deposited. The rotary target may be connected to a shaft configured to rotate in at least one operational state of the system. The rotary target may be connected to the shaft directly or indirectly via a connecting element. According to some embodiments, the rotary targets in a deposition chamber may be exchangeable. Replacement of the rotary targets after the material to be sputtered has been consumed may be made possible.

In embodiments, the system may be configured for sputtering of a transparent conductive oxide film. The system may be configured for deposition of materials like ITO, IZO, IGZO or MoN. In embodiments, the system may be configured for deposition of metallic material. The system may be configured for deposition of electrodes, particularly transparent electrodes in displays, particularly OLED displays, liquid crystal displays, and touchscreens. The system may be configured for deposition of electrodes, particularly transparent electrodes in thin film solar cells, photodiodes, and smart or switchable glass.

In embodiments, a target material of a rotary target can be selected from the group consisting of aluminum, silicon, tantalum, molybdenum, niobium, titanium and copper. Particularly, the target material can be selected from the group consisting of aluminum and silicon. The system may be configured to deposit the material via a reactive sputter process. In reactive sputter processes, typically oxides of the target materials are deposited. However, nitrides or oxy-nitrides might be deposited as well.

Any of the features that the plasma confinement of the first rotary target faces the second target and the plasma confinement of the second rotary target faces the first target may have the advantage that a soft deposition is achieved. For example, bombardment of the substrate with high energy particles may be reduced. Damage of the substrate, particularly of a coating on the substrate, may be mitigated. This is particularly advantageous regarding deposition on sensitive substrates or layers, more particularly deposition on substrates having a sensitive coating. For example when depositing electrodes of an OLED, the material may have to be deposited on a highly sensitive layer. Further, via the soft deposition as described herein, an amount of electrons impinging on the substrate may be reduced. A change of a temperature on or near the substrate surface may be reduced. In particular, a lower temperature on or near the substrate surface may be achieved.

Known facing target sputtering (FTS) setups utilize planar targets. A large amount of material is deposited on the neighboring target surface. Deposition of material on target surfaces may for example lead to arcing or flaking of deposited material, particularly of layers of deposited material, from the target. Generally, long-term stability may be impaired in known FTS setups, particularly such that an application in mass production is not feasible. Known FTS setups may have an expected stability of less than one day.

According to embodiments of the present disclosure, a plasma confinement of a first rotary target facing a second rotary target has the advantage that material deposited on a surface of the rotary target may be sputtered again. In the known FTS setup with planar cathodes, only the small amount of material deposited on a race track of a planar cathode may be sputtered again. A stable FTS process for planar targets is difficult or impossible to achieve.

In rotary targets, the removal of material from the target during magnetron sputtering has an improved uniformity than in the case of magnetron sputtering from planar targets. The uniformity in the case of rotary targets is particularly caused by the movement of the target surface relative to the magnetic field due to the rotation of the targets. The amount of material collected on a target surface may be reduced or even eliminated. Arcing may be reduced or even eliminated. Material flaking may be reduced or eliminated. Stability, particularly long term stability of the deposition process may be increased. Use of the FTS concept for mass production may be enabled. Collection efficiency may be increased, particularly due to the effect that an increased amount of material deposited on a target is sputtered again. Collection efficiency is particularly to be understood as the amount of a sputtered material captured by a substrate relative to the total amount of material emitted by a sputtering target. Material utilization may be increased. Material waste and costs may be reduced.

In embodiments, the system 100 may be configured to deposit the material on a substrate 114. The system may further be configured such that the first direction and the second direction deviate from being parallel to a substrate plane by an angle of less than 40°. In the context of the present disclosure, the “substrate plane” particularly refers to a plane of the substrate 114 whereupon the material is deposited. In particular, the first and the second direction may deviate from being parallel to the substrate plane by an angle of for example less than 30°, 20° or 10°. An advantageous configuration may be achieved, wherein bombardment of the substrate with energetic particles is minimized, while at least a satisfactory amount of material is deposited on the substrate. If any of the first and the second direction would highly deviate from being parallel to the substrate plane in a direction towards the substrate, a disadvantageous bombardment of the substrate with energetic particles could ensue. If any of the first direction and the second direction would highly deviate from being parallel to the substrate plane in a direction away from the substrate, an unsatisfactorily low deposition rate on the substrate could ensue. Additionally or alternatively, a waste of target material could arise.

The first direction may correspond to a first angle, particularly a first polar angle of a polar coordinate system. The reference point, particularly the pole, of the polar coordinate system, may be positioned on a rotation axis of the rotary target. The reference direction of the polar coordinate system may be perpendicular to the rotation axis of the rotary target. The deviation of the first direction from being parallel to a substrate plane may refer to a polar coordinate system of the first rotary target. The deviation of the second direction from being parallel to a substrate plane may refer to a polar coordinate system of the second rotary target.

In embodiments, the system may be configured such that the first direction and the second direction deviate from being parallel to a substrate plane by an angle of less than 40°, 30° or 20° towards the substrate and by an angle of less than 10° away from the substrate.

FIG. 2 shows a system 200 for depositing a material, according to embodiments described herein. The first rotary target 102 and the second rotary target 108 are positioned in a deposition chamber 216. A first additional chamber 218 and a second additional chamber 219 may be provided adjacent to the deposition chamber. According to some embodiments, which can be combined with other embodiments described herein, depositing a material over the substrate can be provided with a dynamic deposition process. For example, the substrate can move past the first rotary target and the second rotary target while material is deposited. The deposition chamber or regions of a vacuum processing system may be separated from further chambers or other regions by a valve.

According to some embodiments, process gases can include any of inert gases such as argon, and reactive gases such as oxygen, nitrogen, hydrogen and ammonia (NH3), Ozone (O3), activated gases or the like.

The substrate 114 is shown to be provided on a substrate carrier 224. Within the deposition chamber 216, rollers 222 may be provided for transport of the substrate carrier 224 into and out of the deposition chamber 216. An exemplary movement direction of the substrate carrier is indicated by arrow 232. The term “substrate” as used herein shall embrace both inflexible substrates, e.g., a glass substrate, a wafer, slices of transparent crystal such as sapphire or the like, or a glass plate, and flexible substrates, such as a web or a foil. According to yet further embodiments, which can be combined with other embodiments described herein, transportation of the substrate and/or substrate carrier, respectively, can be provided by a magnetic levitation system. A carrier can be levitated or can be held without mechanical contact or with reduced mechanical contact by magnetic forces and may be moved by magnetic forces.

The first rotary target 102 and the second rotary target 108 may both be a cathode. The first and the second rotary target may be electrically connected to a DC power supply 230. For example, the chamber housing or one or more shieldings within the vacuum chamber can be provided on mass potential, as indicated by reference numeral 220. These components may serve as an anode. Optionally, a system may further include anodes. In embodiments, which can be combined with other embodiments described herein, at least one or more of the rotary targets may be electrically connected to a respective individual power supply. In particular, each of the rotary targets may be connected to a respective individual power supply. For example, the first rotary target may be connected to a first DC power supply and the second rotary target may be connected to a second DC power supply.

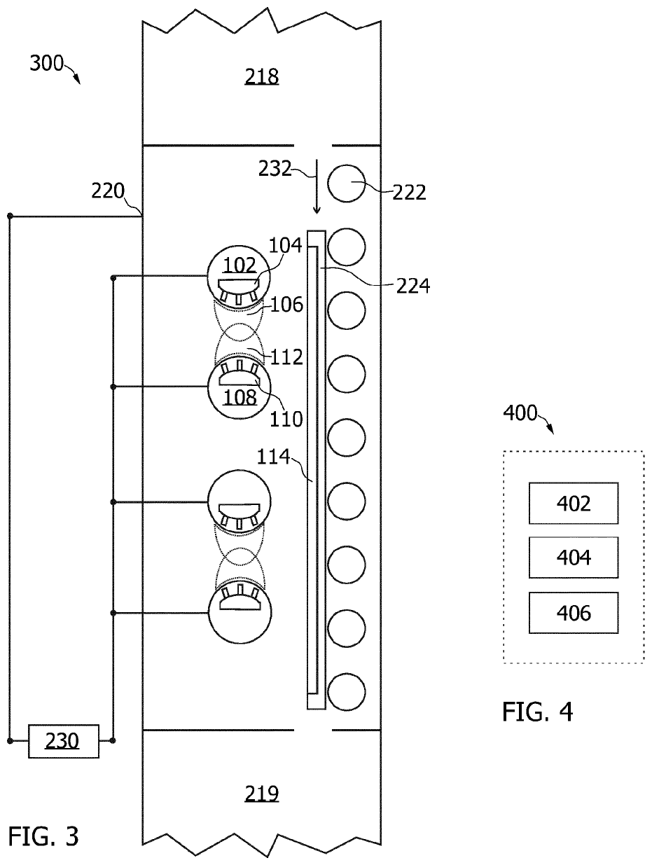

FIG. 3 shows a system for depositing a material, according to embodiments described herein. The system 300 may include a plurality of rotary targets. As an example, four rotary targets are shown. The system may include at least one pair of rotary targets including a first rotary target 102 and a second rotary target 108 with properties as described regarding FIGS. 1 and 2.

According to some embodiments, which can be combined with other embodiments described herein, particularly for applications for large area deposition, an array of cathodes or cathode pairs can be provided. The array may include two or more cathodes or cathode pairs, e.g. three, four, five, six or even more cathodes or cathode pairs. The array may be provided in one deposition chamber.

The present disclosure further relates to a controller configured to be connectable to a system for depositing a material. The controller is further configured to control the system such that a method according to embodiments described herein is performed.

The controller may include a central processing unit (CPU), a memory and, for example, support circuits. To facilitate control of the system, the CPU may be one of any form of general purpose computer processor that can be used in an industrial setting for controlling various components and sub-processors. The memory is coupled to the CPU. The memory, or a computer readable medium, may be one or more readily available memory devices such as random access memory, read only memory, a floppy disk, a hard disk, or any other form of digital storage either local or remote. The support circuits may be coupled to the CPU for supporting the processor in a conventional manner. These circuits include cache, power supplies, clock circuits, input/output circuitry and related subsystems, and the like.

Control instructions are generally stored in the memory as a software routine or program. The software routine or program may also be stored and/or executed by a second CPU that is remotely located from the hardware being controlled by the CPU. The software routine or program, when executed by the CPU, transforms the general purpose computer into a specific purpose computer (controller) that controls a system for depositing a material, according to any of the embodiments of the present disclosure.

Methods of the present disclosure may be implemented as a software routine or program. At least some of the method operations disclosed herein may be performed via hardware as well as by a software controller. As such, the embodiments may be implemented in software as executed upon a computer system, and hardware as an application specific integrated circuit or other type of hardware implementation, or a combination of software and hardware. The controller may execute or perform a method of depositing a material on a substrate, according to embodiments of the present disclosure. Methods described herein can be conducted using computer programs, software, computer software products and interrelated controllers, which can have a CPU, a memory, a user interface, and input and output devices being in communication with corresponding components of the system for depositing a material.

The present disclosure further relates to a method of depositing a material on a substrate. The material may include for example any of ITO and IZO. The method includes sputtering at least a component of the material from a first rotary target with a first magnet assembly and a second rotary target with a second magnet assembly. The first magnet assembly within the first rotary target provides a first plasma confinement in a first direction facing towards the second rotary target. The second magnet assembly within the second rotary target provides a second plasma confinement in a second direction facing towards the first rotary target.

Particularly in embodiments where non-reactive sputtering is performed, the material to be deposited on the substrate may be sputtered from the first and the second rotary target. This is particularly to be understood such that particles ejected from a surface of the first or second rotary target form the deposited material. Particularly in embodiments where reactive sputtering is performed, particles of a first material may be ejected from a surface of the first or the second target. The particles of the first material may combine with a second material to form the material to be deposited on the substrate. The first material can be understood to be a component of the deposited material. A gas surrounding the first and the second rotary target may include the second material.

In embodiments, the first direction and the second direction deviate from being parallel to a substrate plane by an angle of less than 40°. In particular, the first and the second direction may deviate from being parallel to a substrate plane by an angle of less than 30°, 20° or 10°. In embodiments, the first direction and the second direction deviate from being parallel to a substrate plane by an angle of less than 40°, 30° or 20° towards the substrate and by an angle of less than 10° away from the substrate.

According to embodiments described herein, which can be combined with other embodiments described herein, the plasma associated with the sputtering and the substrate are moved relative to each other for deposition of material on the substrate.

Generally, the magnet assemblies may be held still during deposition of the material on a substrate. In embodiments, the magnet assemblies can be moved relative to each other and/or relative to the substrate during deposition, e.g. in an oscillating or back-and-forth manner. A uniformity of a deposited layer may be increased.

FIG. 4 is a chart illustrating a method of depositing a material on a substrate, according to embodiments described herein. The method 400 includes adapting a first magnet assembly of a first rotary target such that the first magnet assembly provides a first plasma confinement in a first direction facing a second rotary target, in block 402. The method further includes adapting a second magnet assembly of the second rotary target such that the second magnet assembly provides a second plasma confinement in a second direction facing the first rotary target, in block 404. Especially in embodiments where the magnet assembly includes a permanent magnet, adapting the magnet assembly may be understood as providing the magnet assembly at a specific position within the rotary target, particularly with a specific orientation. The method further includes depositing a material on a substrate by sputtering at least a component of the material from the first and the second rotary target, in block 406.

Embodiments described herein can be utilized for Display PVD, i.e. sputter deposition on large area substrates for the display market. According to some embodiments, large area substrates or respective carriers, wherein the carriers have a plurality of substrates, may have a size of at least 0.67 m². Typically, the size can be about 0.67 m2 (0.73×0.92 m−Gen 4.5) to about 8 m², more typically about 2 m² to about 9 m² or even up to 12 m². Typically, the substrates or carriers, for which the structures, apparatuses, such as cathode assemblies, and methods according to embodiments described herein are provided, are large area substrates as described herein. For instance, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

While the foregoing is directed to some embodiments, other and further embodiments may be devised without departing from the basic scope of the disclosure. The scope is determined by the following claims.

1. A method of depositing a material on a substrate, the method comprising:
sputtering at least a component of the material from a first rotary target with a first magnet assembly and a second rotary target with a second magnet assembly,
the first magnet assembly within the first rotary target providing a first plasma confinement in a first direction facing towards the second rotary target, and
the second magnet assembly within the second rotary target providing a second plasma confinement in a second direction facing towards the first rotary target.

2. The method according to claim 1, wherein the first direction and the second direction deviate from being parallel to a substrate plane by an angle of less than 40°.

3. The method according to claim 1, wherein the first direction and the second direction deviate from being parallel to a substrate plane by an angle of less than 40° towards the substrate and by an angle of less than 10° away from the substrate.

4. The method according to claim 1, wherein the material deposited on the substrate forms a transparent conductive oxide film.

5. The method according to claim 1, wherein the material comprises ITO or IZO.

6. A controller configured to be connectable to a system for depositing a material and further configured to control the system such that a method of depositing a material on a substrate is performed, the method comprising:
sputtering at least a component of the material from a first rotary target with a first magnet assembly and a second rotary target with a second magnet assembly,
the first magnet assembly within the first rotary target providing a first plasma confinement in a first direction facing towards the second rotary target, and
the second magnet assembly within the second rotary target providing a second plasma confinement in a second direction facing towards the first rotary target.

7. A system for depositing a material, the system comprising a first rotary cathode with a first magnet assembly and a second rotary cathode with a second magnet assembly, the system being configured such that during deposition of the material:
the first magnet assembly within the first rotary cathode is configured to provide a first plasma confinement in a first direction facing towards the second rotary cathode.

8. The system according to claim 7, the system being configured to deposit the material on a substrate, wherein the first direction deviates from being parallel to a substrate plane by an angle of less than 40°.

9. The system according to claim 7, the system further being configured such that during deposition of the material:
the second magnet assembly within the second rotary cathode provides a second plasma confinement in a second direction facing towards the first rotary cathode.

10. The system according to claim 9, the system being configured to deposit the material on a substrate, wherein the first direction and the second direction deviate from being parallel to a substrate plane by an angle of less than 40°.

11. The system according to claim 10, wherein the first direction and the second direction deviate from being parallel to a substrate plane by an angle of less than 40° towards the substrate and by an angle of less than 10° away from the substrate.

12. The system according to claim 7, wherein the deposited material forms a transparent conductive oxide film.

13. The system according to claim 7, wherein the material comprises ITO or IZO.
